(19) United States
(12) Patent Application Publication
(10) Pub. No.: US 2026/0244824 A1
(43) Pub. Date: Aug. 20, 2026

(54) HEIRARCHAL COMPUTER ARCHITECTURE FOR ELECTRONIC DEVICE DEVELOPMENT

(71) Applicant: Lucca Fabani, San Diego, CA (US)

(72) Inventor: Lucca Fabani, San Diego, CA (US)

(21) Appl. No.: 19/057,339

(22) Filed: Feb. 19, 2025

(51) Int. Cl. G06F 30/27; G06N 20/00

(52) U.S. Cl. CPC G06F 30/27; G06N 20/00

(57) ABSTRACT

A system, method and apparatus is described for aiding electronic device design. Developers send queries related to the design of a desired electronic device to a hierarchical, artificial intelligence-based system that automatically generates relevant responses to the queries. The system is arranged in a hierarchical structure, with a primary supervisor initially receiving queries and, for each query, generating a plan that indicates how to process each query. Queries are then sent to a particular, lower-level supervisor. Each query is routed to a particular subservient client subservient client that generates a response to each query. Responses may be validated by the subservient client, or any supervisor that handled the query, to ensure that each response adequately answers each query.

### BACKGROUND

### I. Field of Use

The present application relates generally to the design and development of electronic devices. More specifically, the present application describes embodiments of a method, system and apparatus using artificial intelligence to aid in the design and development of electronic devices.

### II. Description of the Related Art

The Internet-of-Things (“IoT”) is a buzzword that describes the recent proliferation of small, battery-powered electronic devices, such as security sensors, environmental sensors, HVAC sensors, power sensors, water sensors, temperature sensors, etc. Such IoT sensors typically utilize wireless, low-power communication technology and protocols, such as Z-wave, Zigbee, Thread, Matter, Bluetooth, etc.

One of the challenges of developing such IoT sensors is that they have been traditionally difficult to develop, especially from a firmware perspective. Even though several IoT, wireless protocols have been in existence for many years, some of them are not well-documented, contain bugs, and are not well-supported by chip developers. This difficulty results in products that take significantly longer to develop and bring to market, typically on the order of years, even by experienced developers.

### SUMMARY

Embodiments of the present invention are directed towards systems, methods and apparatus for aiding development of electronic devices. In one embodiment, a system is described, comprising a primary supervisor configured to receive a query from a developer of an electronic device, the query comprising an identification of a particular wireless communication protocol associated with the electronic device, to determine where to route the query, to receive a response to the query, and to send the response back to the developer, a plurality of protocol supervisors, each of the plurality of protocol supervisors coupled to the primary supervisor, each of the plurality of protocol supervisors configured to process the query in accordance with the particular wireless communication protocol identified in the query, respectively, to receive the response and forward the response to the primary supervisor, and a plurality of subservient clients, each of the plurality of subservient clients coupled to a respective one of the plurality of protocol supervisors, each of the subservient clients configured to process the query in accordance with a particular aspect of the design of the electronic device, and to receive an LLM response, respectively, to generate the response from the LLM response, and to provide the response to a first protocol supervisor of the plurality of protocol supervisors that provided the query.

In another embodiment, a method is described for aiding electronic device development, comprising receiving a query, by a primary supervisor, from a developer of an electronic device, the query comprising an identification of a particular wireless communication protocol associated with the electronic device, determining, by the primary supervisor, where to route the query, routing the query to a first protocol supervisor of a plurality of protocol supervisors coupled to the primary supervisor, the first protocol supervisor, the first protocol supervisor configured to process queries related to a first wireless communication protocol associated with the query and the electronic device, determining, by the first protocol supervisor, where to route the query, routing the query to a first subservient client of a plurality of subservient clients coupled to the first protocol supervisor, the first subservient client configured to process the query in accordance with a particular aspect of the design of the electronic device, processing, by the first subservient client, the query in accordance with the particular aspect, wherein processing comprises applying the query to an LLM, receiving an LLM response, generating the response from the LLM response, and providing the response to the first protocol supervisor, providing, by the first protocol supervisor, the response to the primary supervisor and providing, by the primary supervisor, the response to the developer.

### BRIEF DESCRIPTION OF THE DRAWINGS

The features, advantages, and objects of the present invention will become more apparent from the detailed description as set forth below, when taken in conjunction with the drawings in which like referenced characters identify correspondingly throughout, and wherein:

FIG. 1 is a functional block diagram of one embodiment of a hierarchical, artificial intelligence architecture system;

FIG. 2 is a functional block diagram of an alternative embodiment of the system shown in FIG. 1, wherein an additional layer of “device type” supervisors have been added;

FIG. 3 is a functional block diagram of one embodiment of any of primary supervisor, other supervisors and subservient clients in the system as shown in FIG. 1; and

FIGS. 4A-4B represent a flow diagram illustrating one embodiment of a method for aiding engineering development of electronic devices.

### DETAILED DESCRIPTION

Described are embodiments of a system, method and apparatus for aiding engineers design and develop new electronic devices. A hierarchical, artificial intelligence architecture is described, comprising a plurality of autonomous supervisors and clients, language models and software tools. In one embodiment, the architecture is structured specifically to aid in the development of battery-powered, IoT devices in a number of different wireless communication protocols. The hierarchical nature of the architecture results in improved accuracy of artificial intelligence responses to queries submitted by engineers in various aspects of development, including documentation retrieval, firmware development, hardware design, RF design, board layout, obtaining a bill of materials, etc.

The term “LLM”, as used herein, may refer to a trained neural network model stored in a physical memory, including large language models and associated software tools that aid an LLM in processing queries from development engineers. A trained neural network model is a set of processor-executable instructions, executed by a related processor, for processing queries to generate “responses” in the form of “plans”, “LLM responses” and responses to the user queries. Reference to an LLM herein may refer to a combination of the processor-executable instructions, a memory for storing the instructions and the software tools, and a hardware processor for executing the instructions and the software tools. The term “software tools”, as used herein, may be used interchangeably with the term “functions,” comprising processor-executable instructions stored in the same or a different physical memory of an LLM, each software tool for performing a particular function that aids an associated LLM to make decisions and answer queries. Examples of such software tools comprise APIs that allow an LLM to communicate with external entities to receive information external to an LLM, search tools that allow an LLM to search the Internet or specific domains, tools that generate source code, schematics, board layouts, bills of material, etc.

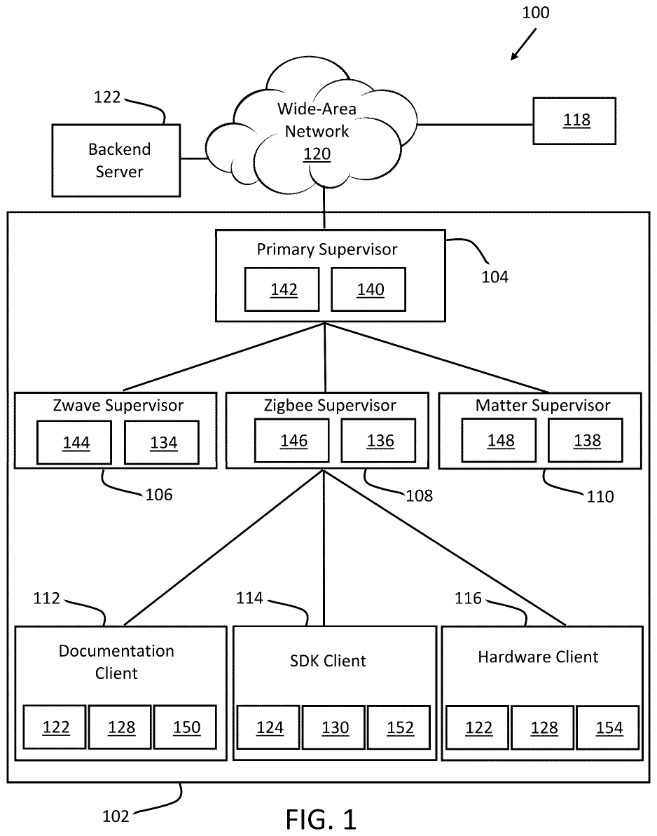

FIG. 1 is a functional block diagram of one embodiment of a hierarchical, artificial intelligence architecture system 100. System 100 is specifically configured to aid in the development of electronic devices and, in some embodiment, specifically to aid in the development of battery-powered, IoT devices, such as low-power, network-capable devices. Engineers and developers of battery-powered electronic devices may use system 100 to ask questions about various aspects of device development, such as questions related to wireless communication protocol documentation, questions related to software development and software development kits (SDKs) that support one or more wireless communication protocols, questions that relate to hardware design, RF design, board layouts, bill of materials, etc. In response, system 100 processes the questions by intelligently routing the questions to various autonomous supervisors and clients in system 100, based on design aspects of an electronic device under development, such as a particular wireless communication protocol and device type. Each supervisor and client in system 100 comprises a processing device, such as a computer, a server, or discreet components (such as a processor, memory, supporting circuitry, etc.) that incorporates or uses a large language model (LLM) to interact with various software tools accessible by the LLMs to perform complex tasks. Each supervisor and client is configured to process queries in accordance with an “aspect” of an electric device under development, such as a particular wireless communication protocol, an electronic device type, hardware design (such as schematics, board layouts, bills of material, etc.), software generation (including source code, object code, executable code, firmware, etc.), documentation retrieval, etc.

“Supervisors” may generate “plans” when queries are received, each plan a listing of actions or steps to be taken in order to answer the query satisfactorily and also identifying a lower-level supervisor or client to pass the query to. A “subservient client” receives queries from upper-tier supervisors and is an “end point” in system 100 where responses to queries are generated. Responses to queries may take the form of text, images, video, source code files, schematic files, bills of materials, circuit board layout files, etc.

While FIG. 1 shows a dedicated LLM associated with each supervisor and subservient client, in other embodiments, two or more an supervisors may utilize the same LLM.

As shown in FIG. 1, system 100, in one embodiment, comprises a computer server 102 comprising a primary supervisor 104, a plurality of protocol supervisors, in this embodiment, a Zwave supervisor 106, a Zigbee supervisor 108 and a Matter supervisor 110. Each protocol supervisor may be coupled to a plurality of subservient clients, shown in FIG. 1 as a documentation client 112, a software development kit (SDK) client 114 and a hardware client 116. Although not shown in FIG. 1, Zwave supervisor 106 and matter supervisor 110 are each coupled to one or more subservient clients and, in one embodiment, to a similar documentation client, SDK client and a hardware client. In other embodiments, each of the protocol supervisors may be coupled to a greater or fewer number of subservient clients that will perform the same or different functions as other subservient clients of the various protocol supervisors.

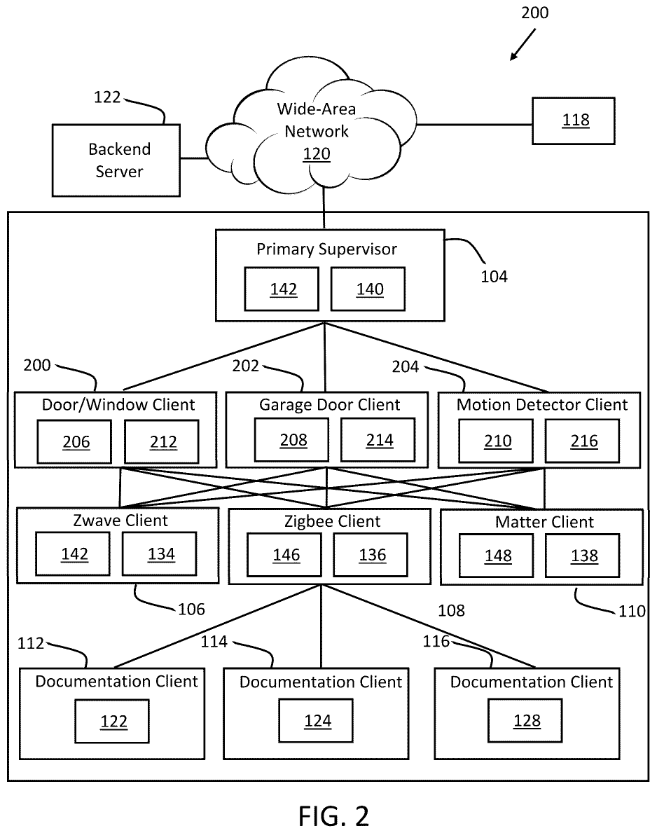

It should be understood that although the architecture of system 100 shown in FIG. 1 shows protocol supervisors 106, 108 and 110 between primary supervisor 104 and subservient 112, 114 and 116, in other embodiments, a different system 200 may be used. For example, FIG. 2 illustrates an alternative embodiment, wherein an additional layer of “device type” supervisors have been added, namely a “security door/window sensor” supervisor 200, a “garage door opener” supervisor 202, and a “motion sensor” supervisor 204. In this embodiment, each of security door/window sensor” supervisor 200, a “garage door opener” supervisor 202, and a “motion sensor” supervisor 204 comprises an LLM with available software tools and a validator, shown as LLM 206, LLM 208 and LLM 210, respectively, and validator 212, validator 214 and validator 216, respectively. Each of the device type supervisors receive queries from primary supervisor 104 when any query is associated with a particular electronic device type under development. For example, when primary supervisor 104 determines that a query is associated with a garage door opener device, the query is routed to the garage door opener supervisor. Each device type supervisor, in turn, determines where to route queries based on a wireless communication protocol associated with the electronic device under development and identified in the queries. Each of the device type supervisors are coupled to each of the protocol supervisors, as shown. Each of the protocol supervisors are, in turn, coupled to a plurality of subservient clients, similar to what is shown and described with respect to FIG. 1 and particularly that each protocol supervisor is coupled to a plurality of subservient clients.

In yet another embodiment, referring again to FIG. 2, different arrangements of the supervisors may be implemented. For example, the device type supervisors may be swapped in exchange for the protocol supervisors that that queries from primary supervisor 104 are routed to one of the protocol supervisors (as in FIG. 1) and then to one of the device type supervisors and onto one of the subservient clients.

Engineers and developers may access system 100 remotely via a client 118 and a wide-area communication network 120. Client 118 comprises a computing device, such as a desktop computer, laptop computer, mobile device, such as of mobile phone, etc. Wide-area communication network 120 comprises one or more communication networks capable of routing communications over large geographic distances, such as cellular communication networks, satellite communication networks and terrestrial-based communication networks, such as the Internet. Queries, typically in textual or voice form, are generated by a user of client 118, such as a hardware engineer/developer, firmware engineer/developer, RF engineer/developer, etc., and received by client 118. Each query is typically relevant to one or more particular aspects of an electronic device under development. For example, queries may be directed towards hardware, firmware, software, RF, protocol documentation, mechanical design, or virtually any aspect of an electronic device under development. Queries may additionally comprise an identification of a desired particular wireless communication protocol of the electronic device under development. These wireless communication protocols may comprise mesh-network protocols such as the well-known Zwave protocol, Zigbee protocol, Matter protocol, etc. Some examples of queries comprise, “show me a block diagram of a typical Zwave glass break sensor”, “give me a listing of all Zigbee command classes”, “give me a schematic and board layout of a typical Matter Wi-Fi camera”, “what is the latest version of Zwave?”, “write source code of implementing a Zwave light sensor”, etc.

Client 118 may access a website or execute a software application that allows users to enter queries and receive responses from system 100. In one embodiment, a backend server 122 may host the website and forward queries from client 118 to system 100, as well as to forward responses from system 100 back to client 118. In one embodiment, backend server 122 may comprise a processor that executes processor-executable instructions that causes backend server 122 to decide where to route each query. For example, if a query clearly indicates that it is associated with a particular wireless communication protocol (for example, a name of a particular wireless communication protocol is included in the query), backend server 122 may process the query, determine that it is related to a particular wireless communication protocol, and forward the query, via wide-area network 120, to the particular protocol supervisor in system 100, bypassing primary supervisor 104. Similarly, a response to the query, once determined by system 100, may be provided by the particular protocol supervisor back to backend server 122 for forwarding to the user via wide-area network 120 and client 118.

In one embodiment, each supervisor and subservient client in system 100 are separate components, some of which may be located within server 102 or external thereto. Each supervisor and subservient client may comprise one or more processors, one or more memories and a network interface. Each supervisor and subservient client may additionally comprise an LLM, one or more software tools associated with the LLM and, for subservient clients, a curated database comprising information associated with a function, aspect, or purpose associated with a particular type of electronic device under development. In one embodiment, one or more of the supervisors and subservient clients may comprise a validator to evaluate responses and determine whether each response adequately answers a user's query. The processor in each supervisor and subservient client executes processor-executable instructions stored in each memory that causes each supervisor to receive queries via the network interface, generate a plan to process each query using an LLM and software tools associated with the LLM, the plan comprising a destination lower-tier supervisor or client where to send each query, forward each query to a destination supervisor or subservient client via the network interface receive responses to the queries via the network interface, evaluate the response in accordance with the plan, and to either forward responses from lower supervisor/clients to upper supervisors or reprocess some of the responses. Lower, subservient clients may determine responses to the queries using a dedicated LLM and software tools associated with each LLM supervisor/subservient client, as will be described in greater detail later herein.

Primary supervisor 104 is coupled to client 118 and, in some embodiments, backend server 122, via wide-area network 120. It is also coupled to one or more other supervisors, in this embodiment, Zwave protocol supervisor 108, Zigbee supervisor 110 and Matter supervisor 112. In general, primary supervisor 104 uses a large language model (LLM) 142 to make decisions on how to process each query received, routing each query to a destination supervisor, receiving responses from the destination supervisor, and in some embodiments, repeating the process until a desired response is achieved. Primary supervisor 104 comprises one or more processors, one or more memories and a network interface for receiving, processing, and forwarding queries, and for receiving responses to the queries and forwarding them to client 118. The memory stores processor-executable instructions that causes primary supervisor 104 to perform these functions. The memory may store LLM 142 and associated software tools for generating plans, route queries in association with each plan and receiving responses to each query. The software tools allow the LLM to access data external to the LLM (via APIs, for example), to search online, generate source code, schematics, board layouts, BOMs, etc.

Each of the protocol supervisors is configured to process queries sent by primary supervisor 104 in accordance with a particular wireless communication protocol of each particle supervisor, respectively. Upon receipt of a query from primary supervisor 104, a particle protocol supervisor typically generates a plan describing how, when and where to process the query, similar to the plan formulated by primary supervisor 104. The plan is generated using an LLM particular to each protocol supervisor, respectively, with the aid of one or more software tools, such as APIs and function calls to processes such as searching, retrieving, writing, creating source code, schematics, bills of material, board layouts, etc. After the plan has been generated, a protocol supervisor may route the query to one of a plurality of subservient clients.

Each subservient client is configured to process queries sent by a particular protocol supervisor in accordance with a particular wireless communication protocol in alignment with the protocol supervisor that sent the query. Each subservient client comprises an LLM particular to each subservient client, respectively, as well as APIs and function calls that allow each subservient client to formulate “LLM responses” to each query, the LLM response particular to a particular wireless communication protocol associated with the electronic device under development. In the embodiment shown in FIGS. 1 and 2, three subservient clients are shown: documentation client 112, SDK client 114 and hardware client 116. Each subservient client comprises an LLM stored in a respective memory: LLM 122 associated with documentation client 112, LLM 124 associated with SDK client 114 and LLM 126 associated with hardware client 116. Each of the subservient clients typically each comprise a curated database, for example, documentation client 112 comprises database 150, SDK client 114 comprises database 152 and hardware client 116 comprises database 154. Each curated database is accessed by a respective LLM using the software tools, each curated database comprising information associated with a function, aspect or purpose associated with each query. For example, SDK client 114 is configured to process queries related to a) electronic devices that use the Zigbee protocol and specifically, b) queries associated with a particular SDK used to develop firmware for an intended electronic device. Thus, database 152 contains information related to a Zigbee SDK but does not typically comprise information regarding other functions, design aspects or purposes unrelated to a Zigbee SDK. Similarly, database 150 contains information related to Zigbee documentation while database 154 contains information related to Zigbee hardware design. In one embodiment, each curated database comprises a vector database, such as a vector database provided by Pinecone or Redis Enterprise.

In one embodiment, one or more of the subservient clients may be configured to validate the LLM results from each LLM, respectively. FIG. 1 shows validator 128 associated with documentation client 112, validator 130 associated with SDK client 114 and validator 130 associated with hardware client 116. Each of the validators comprise a processor and an LLM that receives LLM results from either a respective subservient client or directly from an LLM associated with a respective subservient client. The LLM responses are processed by each respective validators' LLM, in some embodiments, generating a confidence level that the LLM response adequately answers each query. When the confidence level exceeds a predetermined threshold, a validator will provide an indication to a respective subservient client, indicating that the LL and response properly answers each query. In other embodiments, a confidence value is not generated and responses are forwarded when they are validated, i.e., sent to an LLM, along with an associated query, wherein the LLM processes each response and associated query in accordance with its training to determine whether each response adequately answers each respective query.

Validators may be also used by supervisors and primary supervisor 104 to validate results provided by lower-level subservient/supervisors and/or to validate LLM responses from LLMs within the same supervisor. For example, FIG. 1 shows Zwave supervisor 106 comprising validator 134, Zigbee supervisor 108 comprising validator 136, and Matter supervisor 110 comprising validator 138. Each of these validators are used to either validate responses from subservient clients or to validate plans as they are generated by each supervisor. Similarly, primary supervisor 104 may comprise a validator 140. Of course, in other embodiments, validators may be used by only some of the supervisors and clients of system 100.

In some embodiments, validators are not used, and responses are evaluated by each respective supervisor to determine whether to route each response to client 118 or whether to reprocess queries associated with rejected responses.

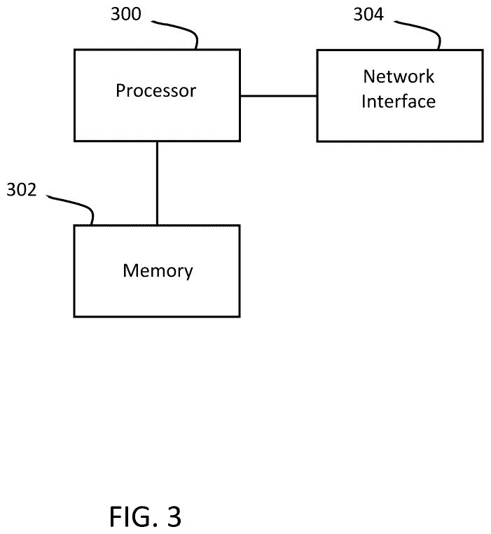

FIG. 3 is a functional block diagram of one embodiment of any of primary supervisor 104, other supervisors and subservient clients in system 100. FIG. 3 shows processor 300, memory 302, and network interface 304. It should be understood that these functional blocks may be connected to one another in a variety of ways and that not all functional blocks are necessary for operation of a client is shown (such as a power supply), for purposes of clarity.

Processor 300 is configured to provide operational functionality of any supervisor or client of system 100 by executing processor-executable instructions, i.e., executable software, stored in a respective memory 302. Operational functionality comprises one or more of receiving queries, generating plans, routing queries, generating responses, verifying LLM responses and/or forwarding responses, etc. Processor 300 typically comprises one or more programmable microprocessors, microcomputers, microcontrollers, custom ASICs, System-on-Chips (SoCs), System-in-Packaging (SiP), or the like, and where two or more processors are used, each of the processors, either alone or in combination, may execute one or more of the processor-executable instructions that cause the processor to perform various functions. Processor 300 may be selected based on a variety of factors, including power-consumption, size, and cost. While processor 300 is typically referred to herein as a singular “processor”, in some embodiments, such reference may include one or more additional processors.

Memory 302 is coupled to processor 300, comprising one or more information storage devices, such as RAM, ROM, flash memory, or some other type of electronic, optical, or mechanical memory device(s). Memory 302 is used to store processor-executable instructions for functional operation of any of the supervisors or clients in system 100. Memory 302 may be used to store LLMs, APIs and other software tools that enable functionality of the supervisors and clients in system 100. While memory 302 is typically referred to herein as a singular “memory”, in some embodiments, such reference may include one or more additional memories of the same or different type.

It should be understood that memory 302 is non-transitory, i.e., it excludes propagating signals, and that memory 302 could be incorporated into processor 300, for example, when processor 300 is, for example, a complex, multi-function device, an SoC. It should also be understood that once the processor-executable instructions are loaded into memory 302, processor 300 may be considered to be a specialized processor for performing the functional operations of a supervisor or a subservient client of system 100.

Network interface 304 is coupled to processor 300, comprising a physical connector or port, along with supporting electronic circuitry, for sending and receiving information between the various supervisors, subservient clients and wide-area network 120 in system 100. Network interface 304 may comprise an Ethernet port, Wi-Fi circuitry or some other network communication interface well-known in the art.

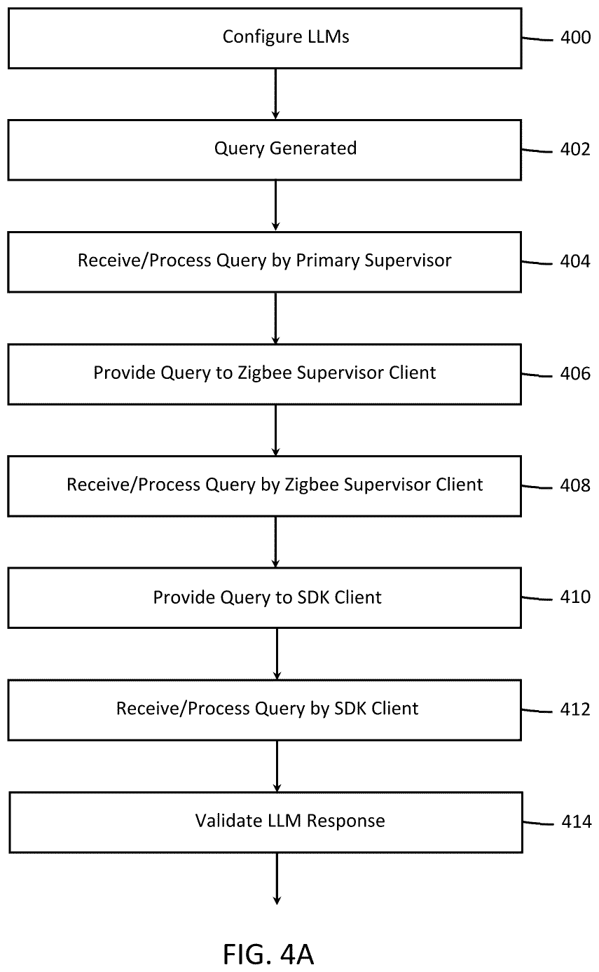

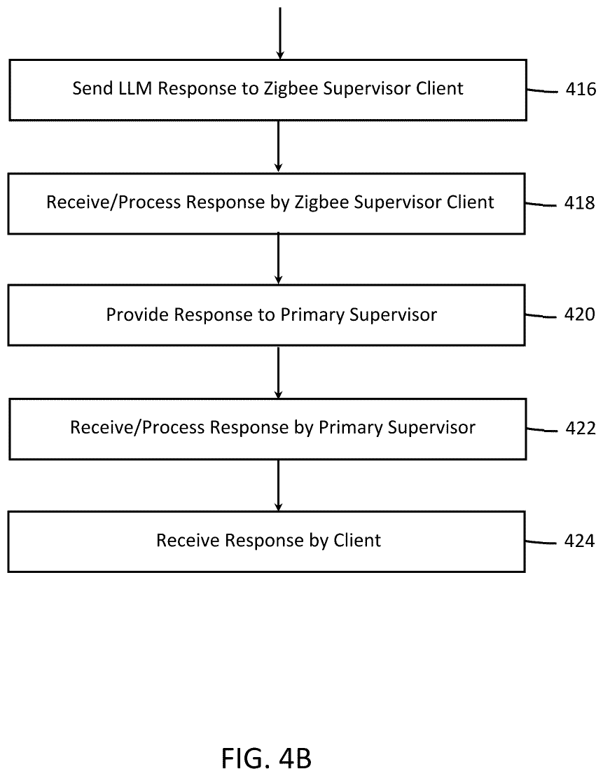

FIGS. 4A-4B represent a flow diagram illustrating one embodiment of a method for aiding engineering development of electronic devices. The method is performed by respective processors operating in various supervisors and subservient clients in system 100, each executing processor-executable instructions stored in respective memories of each of the various supervisors and subservient clients. The method describes how system 100 operates when an electronic device under development comprises a Zigbee motion sensor, however, it should be understood that the method as described could apply to virtually any type of electronic device and any type of wireless communication protocol. Further, reference to any supervisor or subservient client implicitly refers to processing by a respective processor 200 executing respective processor-executable instructions stored in a respective memory 202.

At step 400, one or more LLMs associated with one or more supervisors and/or subservient clients are configured to generate one or more plans, respectively. Each plan comprises a set of instructions for processing queries. Configuration of the LLMs comprises generating a plurality of system prompts by an engineer and providing the system prompts to the LLMs, respectively. Each system prompt comprises a set of instructions, guidelines, and contextual information that act as a framework, setting the stage for an LLM to operate within specific parameters and generate responses that are coherent, relevant, and aligned with desired responses. For example, a system prompt for primary supervisor 104 may look like the following:

“You are primary supervisor named Lucca. Your role is to receive queries from engineers, create a plan for processing each query, forwarding each query to one of a Zwave protocol supervisor, a Zigbee protocol supervisor, and a Matter protocol supervisor in accordance with the plan, receive responses from the protocol supervisors, route the response to an appropriate destination, and create a new plan when a response does not adequately answer a corresponding query correctly. Each plan shall be formatted as a textual JSON instruction in the following format {“steps”: [“Step 1: [task1]”,” Step 2: [task2]”, etc.]}, identifying one of the three protocol supervisors to forward each query.”

A system prompt for a protocol supervisor may look like the following:

“You are protocol supervisor named Tom. Your role is to receive queries related to Zwave from a primary supervisor, create a plan for processing each query, forwarding each query to one of a documentation client, a software development client and a hardware client, receive responses from the clients, verify that each response appropriately answers a corresponding query, create a new plan when a response does not answer a corresponding query correctly, and forward each response back to the supervisor. Each plan shall be formatted as a textual JSON instruction identifying which subservient client to forward each query in the form of {“steps”: [“Step 1: [task1]”,” Step 2: [task2]”, etc.]}.”

A system prompt for a subservient client may look like the following:

“You are a subservient client for a Zigbee supervisor. Your role is to receive hardware-related queries related to the Zigbee protocol and process the queries in accordance with tasks provided by the Zigbee supervisor. You may use a search tool, a schematic creation tool, a BOM tool, and a board layout tool to answer the queries. Responses to the queries may comprise schematics, board layouts, and bills of material. Responses are sent back to the Zigbee supervisor.”

At step 402, a user of client 118 enters a query into client 118, requesting information related to the design of an electronic device. The query may comprise an identification of a particular wireless communication protocol, an identification of a desired electronic device under development, a question or a command related to a wireless communication protocol and/or the desired electronic device. The query is then provided either to backend server 122 or to primary supervisor 104 via wide-area network 120.

At step 404, in one embodiment, the query is received by primary supervisor 104 and the query is processed. Processing may comprise providing the query to LLM 142 for generating a plan for routing the query to a lower-level supervisor or subservient client, determining what to do when a response to the query is received and where to send the response when it is received from a lower-level supervisor. The following is an example of a plan generated by primary supervisor 104 in response to a query, the query comprising
1. Forward the query to Zigbee supervisor 108 with instruction to answer the query
2. Receive response from Zigbee supervisor 108
3. Determine if response adequately answers the query using LLM 142
4. If the response adequately answers the query, route the response to client 118
5. If the response does not adequately answer the query, create a new plan on how to process the query

The plan is generated by LLM 142 and related software tools associated with primary LLM 142. In this example, the plan indicates that the query should be sent to Zigbee supervisor 108 and that when a response is received from Zigbee supervisor 108, the response should be validated by LLM 142 and, if validated, sent back to client 118 via wide-area network 120. Otherwise, if the response is not validated, the current plan may be modified, or a new plan created, with different steps of processing the query.

In one embodiment, the query from client 118 is provided to backend server 122 for initial processing. Backend server 122 is typically an online computer server, comprising a processor, memory and a network interface for receiving queries and processing them to determine if queries can be routed directly to a lower-level supervisor, such as to one of the protocol supervisors, bypassing primary supervisor 104. For example, backend server 122 may examine a query and determine, by textual identification techniques well-known in the art, that a query is related to a particular wireless communication protocol supported by one of the protocol supervisors in system 100. In this case, backend server 122 may forward the query directly to one of the protocol supervisors in accordance with a particular wireless communication protocol identified in the query.

In a related embodiment, if backend server 122 fails to identify a lower-level supervisor to process the query, the query may, by default, be sent to primary supervisor 104 for processing.

At step 406, primary supervisor 104 provides the query and, in some embodiment, the task described in the first stop of the plan, in this embodiment, “answer the query”, to a lower-level supervisor, in this embodiment, to Zigbee supervisor 108, in accordance with the plan.

At step 408, the query is received by Zigbee supervisor 108 and the query is processed by LLM 146. In one embodiment, processing comprises generating another plan for routing the query to a lower-level supervisor or a subservient client, determining what to do when a response to the query is received, whether to validate the response and how, and where to send the response when it is received from the lower-level supervisor or subservient client. Like the plan created by primary supervisor 104, this plan is generated by LLM 146 and related software tools. In this example, the plan indicates that, based on the query, the query should be sent to documentation client 112 and that when a response is received from documentation client 112, the response should be validated by LLM 146 and, if validated, sent back to primary supervisor 104. Otherwise, if the response is not validated, a new or revised plan may be created. The following is an exemplary plan formed by Zigbee supervisor 108 in response to receiving the query as outlined above:
1. Use documentation client 112 and a search tool to search Zigbee document database 150 for documents related to the query/command
2. Receive result
3. Use documentation client 112 and a search tool to search Zigbee document database 150 for internal app notes for any additional information to support the query/command
4. Receive result
5. Provide results of steps 1 and 2 to SDK client 114 with instruction to generate Zigbee source code in accordance with the query using a source code generator tool
6. Receive Zigbee source code
7. Validate Zigbee source code10. If valid, send Zigbee source code to Zigbee supervisor 108
8. If not valid, generate a new plan

At step 410, the query is sent to a subservient client, in this embodiment, Zigbee documentation client 112, along with an instruction to return Zigbee documentation related to the query

At step 412, the query is received by documentation client 112 and processed. Processing comprises LLM 122 searching database 150 for documents relating to the query and generating an LLM response containing the documents. LLM 122 processes the query by calling one or more software tools, or functions, i.e., processor-executable instructions stored in memory 202, each function for performing a particular action, such as a search function for searching one or more curated databases, a read and/or write function for retrieving and/or writing data, a code generation function for generating source code, executable code, etc. for use in an electronic device under development, a schematic generation function for generating schematics for use in an electronic device under development, a board layout function, a bill of material function, etc. For example, the search function comprises a search software tool that returns relevant chunks of text, or other information, from curated data sources, such as Zigbee document database 150. In some embodiments, calls to functions result in LLM responses that are provided directly to documentation client 112. In other embodiments, results of function calls are provided to LLM 122, and LLM 122 may validate the response from the function(s) and, when validated, send the same result, or a modified result, as an LLM response to documentation client 112. Depending on how a subservient client is configured, the LLM response may comprise technical documentation related to Zigbee source code.

At step 414, the LLM response may be validated by validator 128 or by documentation client 114 using LLM 122, as described earlier herein. If the response was deemed invalid by validator 128 or documentation client 112 (i.e., the LLM response does not answer the query correctly), documentation client 112 may send the query back to LLM 122 for further processing, i.e., to re-process the query with an indication that the original LLM response did not answer the query. The process of generating an LLM response, invalidating the LLM response and reprocessing may continue for several iterative cycles until an LLM response is deemed valid.

At step 416, the LLM response is sent from documentation client 114 to Zigbee supervisor 108, the LLM response comprising documentation related to Zigbee source code.

At step 418, the response is received by Zigbee supervisor 108 and, in response, Zigbee supervisor 108 processes the next step in the plan, which is to send the query to documentation client 112 to search Zigbee document database 150 for internal app notes for any additional information to support the query. The query is processed as before, using LLM 122 and a software tool, in this case the same search tool used in step 412, is used to return documentation related to Zigbee app notes related to the query. The app notes may then be provided to Zigbee supervisor 108, whereupon Zigbee supervisor 108 processes the next task in the plan, namely, sending the query and the discovered Zigbee documentation to SDK client 114 to generate Zigbee source code in accordance with query.

At step 420, SDK client 114 receives the query and the discovered documentation from Zigbee supervisor 108 and processes the information. Processing may comprise providing the query and discovered documentation to LLM 124, and this information is processed by LLM 124, which may then call a Zigbee source code generation tool to generate the desired Zigbee source code.

At step 422, in one embodiment, the source code may be validated either by SDK client 114 (typically using LLM 246 or by validator 130 to ensure that the source code adequately addresses the query to generate Zigbee source code for a particular function related to a Zigbee electronic device under development.

At step 422, the source code is sent to Zigbee supervisor 108, where it may be validated either by Zigbee supervisor 108 (typically using LLM 146 or by validator 136). Validation may comprise determining what step or action is next in the plan after receiving the source code, and then either accepting the source code and executing the next step in the plan, or generating a revised plan, or a new plan, if the source code is deemed to not adequately provide suitable source code in association with the query. For example, when the source code is deemed to adequately provide suitable code, the source code may be sent as a response to primary supervisor 104. When the source code is deemed to not adequately provide suitable source code, i.e., there are errors in the source code or the source code does not perform the function identified in the query, Zigbee supervisor 108 may re-submit the query back to SDK client 114 for re-evaluation of the query in accordance with the plan. SDK client 114 may then reevaluate the query, in one embodiment with knowledge that the original source code did not adequately provide suitable source code. In one embodiment, the original plan is revised, or a new plan generated, that addresses the inadequate source code, typically comprising steps to send the query back to SDK supervisor 114, or to a different supervisor or subservient client, for reprocessing.

At step 424, Zigbee supervisor 108 passes the source code, now referred to as a “response,” to primary supervisor 104, in accordance with the plan.

At step 426, the response is received by primary supervisor 104 and processed in accordance with the plan generated previously by primary supervisor 104. For example, the plan may indicate that upon receipt of any response, the response is forwarded to client 118 via wide-area network 120. In another embodiment, the plan may indicate that after receipt of a response, the response must be validated, either by primary supervisor 104 or by validator 140, prior to forwarding to client 118. Otherwise, the plan may indicate that the response should be resubmitted to Zigbee supervisor 108 or it may indicate that a new or revised plan should be generated, with knowledge that the response was invalidated. For example, a new plan may indicate that rather than being processed by Zigbee supervisor 108, the query should be processed by Matter supervisor 110.

In step 428, the response is received by client 118 via wide-area network 120. A user of claim 118 may then use the result to aid the user in developing a desired electronic device.

Although specific advantages have been enumerated above, various embodiments may include some, none, or all of the enumerated advantages. Other technical advantages may become readily apparent to one of ordinary skill in the art after review of the foregoing figures and description.

It should be understood at the outset that, although exemplary embodiments are illustrated in the figures and described above, the principles of the present disclosure may be implemented using any number of techniques, whether currently known or not. The present disclosure should in no way be limited to the exemplary implementations and techniques illustrated in the drawings and described above.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set. The article “a” means “one or more”.

In many places in this document, actions (e.g., functionality) are performed by one or more processors executing processor-executable instructions (i.e., software, firmware). This is done for ease of description; it should be understood that, whenever it is described in this document that software performs any action, the action is in actuality performed by underlying hardware elements (such as a processor and a memory device) according to the instructions that comprise the software. Such functionality may, in some embodiments, be provided in the form of firmware and/or hardware implementations.

As used herein, the term LLM or large language model, includes other types of models. Accordingly, whenever it is mentioned herein that an LLM may be used, other types of models may also be used. The models may be neural networks or other types of machine-learned models that provide an output (e.g., a predictive output) from a given input. When prompted, inference may be performed on the indicated model (e.g., the LLM) that then provides a response.

The elements described in this document include actions, features, components, items, attributes, and other terms. Whenever it is described in this document that a given element is present in “some embodiments,” “various embodiments,” “certain embodiments,” “certain example embodiments, “some example embodiments,” “an exemplary embodiment,” “an example,” “an instance,” “an example instance,” or whenever any other similar language is used, it should be understood that the given element is present in at least one embodiment, though is not necessarily present in all embodiments. Consistent with the foregoing, whenever it is described in this document that an action “may,” “can,” or “could” be performed, that a feature, element, or component “may,” “can,” or “could” be included in or is applicable to a given context, that a given item “may,” “can,” or “could” possess a given attribute, or whenever any similar phrase involving the term “may,” “can,” or “could” is used, it should be understood that the given action, feature, element, component, attribute, etc. is present in at least one embodiment, though is not necessarily present in all embodiments.

Terms and phrases used in this document, and variations thereof, unless otherwise expressly stated, should be construed as open-ended rather than limiting. As examples of the foregoing: “and/or” includes any and all combinations of one or more of the associated listed items (e.g., a and/or b means a, b, or a and b); the singular forms “a”, “an”, and “the” should be read as meaning “at least one,” “one or more,” or the like; the term “example”, which may be used interchangeably with the term embodiment, is used to provide examples of the subject matter under discussion, not an exhaustive or limiting list thereof; the terms “comprise” and “include” (and other conjugations and other variations thereof) specify the presence of the associated listed elements but do not preclude the presence or addition of one or more other elements; and if an element is described as “optional,” such description should not be understood to indicate that other elements, not so described, are required.

As used herein, the term “non-transitory computer-readable storage medium” includes a register, a cache memory, a ROM, a semiconductor memory device (such as D-RAM, S-RAM, or other RAM), a magnetic medium such as a flash memory, a hard disk, a magneto-optical medium, an optical medium such as a CD-ROM, a DVD, or Blu-Ray Disc, or other types of volatile or non-volatile storage devices for non-transitory electronic data storage. The term “non-transitory computer-readable storage medium” does not include a transitory, propagating electromagnetic signal.

The claims are not intended to invoke means-plus-function construction/interpretation unless they expressly use the phrase “means for” or “step for.” Claim elements intended to be construed/interpreted as means-plus-function language, if any, will expressly manifest that intention by reciting the phrase “means for” or “step for”; the foregoing applies to claim elements in all types of claims (method claims, apparatus claims, or claims of other types) and, for the avoidance of doubt, also applies to claim elements that are nested within method claims. Consistent with the preceding sentence, no claim element (in any claim of any type) should be construed/interpreted using means plus function construction/interpretation unless the claim element is expressly recited using the phrase “means for” or “step for.”

Whenever it is stated herein that a hardware element (e.g., a processor, a network interface, a display interface, a user input adapter, a memory device, or other hardware element), or combination of hardware elements, is “configured to” perform some action, it should be understood that such language specifies a physical state of configuration of the hardware element(s) and not mere intended use or capability of the hardware element(s). The physical state of configuration of the hardware elements(s) fundamentally ties the action(s) recited following the “configured to” phrase to the physical characteristics of the hardware element(s) recited before the “configured to” phrase. In some embodiments, the physical state of configuration of the hardware elements may be realized as an application specific integrated circuit (ASIC) that includes one or more electronic circuits arranged to perform the action, or a field programmable gate array (FPGA) that includes programmable electronic logic circuits that are arranged in series or parallel to perform the action in accordance with one or more instructions (e.g., via a configuration file for the FPGA). In some embodiments, the physical state of configuration of the hardware element may be specified through storing (e.g., in a memory device) program code (e.g., instructions in the form of firmware, software, etc.) that, when executed by a hardware processor, causes the hardware elements (e.g., by configuration of registers, memory, etc.) to perform the actions in accordance with the program code.

A hardware element (or elements) can therefore be understood to be configured to perform an action even when the specified hardware element(s) is/are not currently performing the action or is not operational (e.g., is not on, powered, being used, or the like). Consistent with the preceding, the phrase “configured to” in claims should not be construed/interpreted, in any claim type (method claims, apparatus claims, or claims of other types), as being a means plus function; this includes claim elements (such as hardware elements) that are nested in method claims.

Although process steps, algorithms, or the like, may be described or claimed in a particular sequential order, such processes may be configured to work in different orders. In other words, any sequence or order of steps that may be explicitly described or claimed in this document does not necessarily indicate a requirement that the steps be performed in that order; rather, the steps of processes described herein may be performed in any order possible. Further, some steps may be performed simultaneously (or in parallel) despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary, and does not imply that the illustrated process is preferred.

Although various embodiments have been shown and described in detail, the claims are not limited to any particular embodiment or example. None of the above description should be read as implying that any particular element, step, range, or function is essential. All structural and functional equivalents to the elements of the above-described embodiments that are known to those of ordinary skill in the art are expressly incorporated herein by reference and are intended to be encompassed. Moreover, it is not necessary for a device or method to address each and every problem sought to be solved by the present invention, for it to be encompassed by the invention. No embodiment, feature, element, component, or step in this document is intended to be dedicated to the public.

We claim:

1. A system for aiding electronic device design, comprising:
a primary supervisor configured to receive a query from a developer of an electronic device, the query comprising an identification of a particular wireless communication protocol associated with the electronic device, to determine where to route the query, to receive a response to the query, and to send the response back to the developer;
a plurality of protocol supervisors, each of the plurality of protocol supervisors coupled to the primary supervisor, each of the plurality of protocol supervisors configured to process the query in accordance with the particular wireless communication protocol identified in the query, respectively, to receive the response and forward the response to the primary supervisor; and
a plurality of subservient clients, each of the plurality of subservient clients coupled to a respective one of the plurality of protocol supervisors, each of the subservient clients configured to process the query in accordance with a particular aspect of the electronic device, and to receive an LLM response, respectively, to generate the response from the LLM response, and to provide the response to a first protocol supervisor of the plurality of protocol supervisors that provided the query.

2. The system of claim 1, wherein the primary supervisory is configured to determine where to route the query by generating a plan in response to receiving the query, the plan comprising a listing of one or more particular protocol supervisors subservient client to process the query.

3. The system of claim 1, further comprising:
a plurality of validators, each coupled to the plurality of subservient clients, respectively, each validator configured to receive the LLM response from a respective subservient client, evaluate the LLM response to determine when the response answers the query and, when the LLM response answers the query, provide the LLM response to a respective one of the subservient clients.

4. The system of claim 1, wherein a first subservient client of the plurality of subservient clients is configured to process the query when the query is associated with documentation-related aspects associated with a first wireless communication protocol of the electronic device.

5. The system of claim 1, wherein a first subservient client of the plurality of subservient clients is configured to process the query when the query is associated with hardware-related aspects associated with the electronic device.

6. The system of claim 1, wherein a first subservient client of the plurality of subservient clients is configured to process the query when the query is associated with hardware-related aspects of a first wireless communication protocol associated with the electronic device, and wherein a second subservient client of the plurality of subservient clients is configured to process the query when the query is associated with documentation-related aspects of the first wireless communication protocol.

7. The system of claim 1, further comprising:
a plurality of LLMs, each of the plurality of LLMs coupled to a respective one of the plurality of subservient clients, each of the plurality of LLMs configured to receive the query from a respective subservient supervisor, to process the query, to generate the LLM response and to provide the LLM response to a respective one of the plurality of subservient clients.

8. A method for aiding electronic device design, comprising:
receiving a query, by a primary supervisor, from a developer of an electronic device, the query comprising an identification of a particular wireless communication protocol associated with the electronic device;
determining, by the primary supervisor, where to route the query;
routing the query to a first protocol supervisor of a plurality of protocol supervisors coupled to the primary supervisor, the first protocol supervisor, the first protocol supervisor configured to process queries related to a first wireless communication protocol associated with the query and the electronic device;
determining, by the first protocol supervisor, where to route the query;
routing the query to a first subservient client of a plurality of subservient clients coupled to the first protocol supervisor, the first subservient client configured to process the query in accordance with a particular aspect of the electronic device;
processing, by the first subservient client, the query in accordance with the particular aspect, wherein processing comprises processing the query via an LLM, receiving an LLM response, generating the response from the LLM response, and providing the response to the first protocol supervisor;
providing, by the first protocol supervisor, the response to the primary supervisor; and
providing, by the primary supervisor, the response to the developer.

9. The method of claim 8, wherein determining, by the first protocol supervisor, where to route the query comprises generating a plan in response to receiving the query, the plan comprising a listing of one or more particular subservient clients subservient client to process the query.

10. The method of claim 8, further comprising:
validating, by a first validator of a plurality of validators coupled to the first subservient client, the LLM response, evaluate the LLM response to determine when the LLM response answers the query and, when the LLM response answers the query, provide the LLM response to the first subservient client.

11. The method of claim 8, wherein a first subservient client of the plurality of subservient clients is configured to process the query when the query is associated with documentation-related aspects associated with a first wireless communication protocol of the electronic device.

12. The method of claim 8, wherein a first subservient client of the plurality of subservient clients is configured to process the query when the query is associated with hardware-related aspects associated with a first wireless communication protocol of the electronic device.

13. The method of claim 8, wherein a first subservient client of the plurality of subservient clients is configured to process the query when the query is associated with hardware-related aspects associated with a first wireless communication protocol of the electronic device, and wherein a second subservient client of the plurality of subservient clients is configured to process the query when the query is associated with documentation-related aspects associated with the first wireless communication protocol of the electronic device.

14. The method of claim 8, further comprising:
receiving, by the LLM, the query from the first subservient supervisor;
generating, by the LLM, an LLM response; and
providing the LLM response to the first subservient client.
